(19) United States
(12) Patent Application Publication
(10) Pub. No.: US 2017/0200731 A1
(43) Pub. Date: Jul. 13, 2017

(54) SEMICONDUCTOR MEMORY DEVICE AND METHOD FOR MANUFACTURING SAME

(71) Applicant: Kabushiki Kaisha Toshiba, Minato-ku (JP)

(72) Inventors: Yuta YOSHIMOTO, Taito (JP); Sachiyo ITO, Kawasaki (JP); Tatsuhiro ODA, Yokohama (JP); Toru MATSUDA, Yokkaichi (JP)

(73) Assignee: Kabushiki Kaisha Toshiba, Minato-ku (JP)

(21) Appl. No.: 15/392,667

(22) Filed: Dec. 28, 2016

(30) Foreign Application Priority Data
Jan. 8, 2016 (JP) 2016-003060

(51) Int. Cl. H01L 27/11568; H01L 27/11578

(52) U.S. Cl. CPC H01L 27/11568; H01L 27/11578

(57) ABSTRACT

According to an embodiment, a semiconductor memory device includes a stacked body, a semiconductor pillar, a memory film, a first structure body, and a first connection portion. The stacked body includes a first conductive layer and a second conductive layer. The semiconductor pillar extends in the first direction through the stacked body. The memory film provides between the stacked body and the semiconductor pillar. The first conductive layer includes a first region and a second region. The first region does not overlap the second conductive layer in the first direction. The second region overlaps the second conductive layer in the first direction. The first structure body extends in the first direction through the first region to a position of a front surface of the first region. The first connection portion is electrically connected to the first conductive layer.

### CROSS-REFERENCE TO RELATED APPLICATIONS

This application is based upon and claims the benefit of priority from Japanese Patent Application No. 2016-003060, filed on Jan. 8, 2016; the entire contents of which are incorporated herein by reference.

### FIELD

An embodiment described herein relate generally to a semiconductor memory device and a method for manufacturing the same.

### BACKGROUND

A three-dimensionally stacked semiconductor memory device has been proposed in which memory cells are integrated three-dimensionally. Higher density is desirable in such a semiconductor memory device.

### BRIEF DESCRIPTION OF THE DRAWINGS

FIG. 1 is a cross-sectional view illustrating a semiconductor memory device according to an embodiment;

FIG. 2 is a plan view illustrating the semiconductor memory device according to the embodiment;

FIG. 3 is cross-sectional view of process, illustrating the method for manufacturing the semiconductor memory device according to the embodiment;

FIG. 4 is cross-sectional view of process, illustrating the method for manufacturing the semiconductor memory device according to the embodiment;

FIG. 5 is a plan view illustrating the method for manufacturing the semiconductor memory device according to the embodiment;

FIG. 6 is a cross-sectional view of process, illustrating the method for manufacturing the semiconductor memory device according to the embodiment;

FIG. 7 is a cross-sectional view of process, illustrating the method for manufacturing the semiconductor memory device according to the embodiment;

FIG. 8 is a cross-sectional view of process, illustrating the method for manufacturing the semiconductor memory device according to the embodiment;

FIG. 9 is a plan view illustrating the method for manufacturing the semiconductor memory device according to the embodiment;

FIG. 10 is a cross-sectional view of process, illustrating the method for manufacturing the semiconductor memory device according to the embodiment;

FIG. 11 is a cross-sectional view of process, illustrating the method for manufacturing the semiconductor memory device according to the embodiment;

FIG. 12 is a process plan view illustrating the method for manufacturing the semiconductor memory device according to the embodiment;

FIG. 13 is a cross-sectional view of a process, illustrating the method for manufacturing the semiconductor memory device according to the embodiment;

FIG. 14A and FIG. 14B are perspective views illustrating a portion of the semiconductor memory device;

FIG. 15A to FIG. 15C illustrate a portion of the semiconductor memory device;

FIG. 16 is a cross-sectional view illustrating the semiconductor memory device according to the embodiment;

FIG. 17A and FIG. 17B are schematic cross-sectional views illustrating a portion of the semiconductor memory device; and

FIG. 18 is a perspective view illustrating the semiconductor memory device according to the embodiment.

### DETAILED DESCRIPTION

According to an embodiment, a semiconductor memory device includes a stacked body, a semiconductor pillar, a memory film, a first structure body, and a first connection portion. The stacked body includes a first conductive layer and a second conductive layer. The second conductive layer separates, with a first insulating region interposed, from the first conductive layer in a first direction. The semiconductor pillar extends in the first direction through the stacked body. The memory film provides between the stacked body and the semiconductor pillar. The first conductive layer includes a first region and a second region. The first region does not overlap the second conductive layer in the first direction. The second region overlaps the second conductive layer in the first direction. The first structure body extends in the first direction through the first region to a position of a front surface of the first region. The first connection portion is electrically connected to the first conductive layer.

An embodiment of the invention will now be described with reference to the drawings.

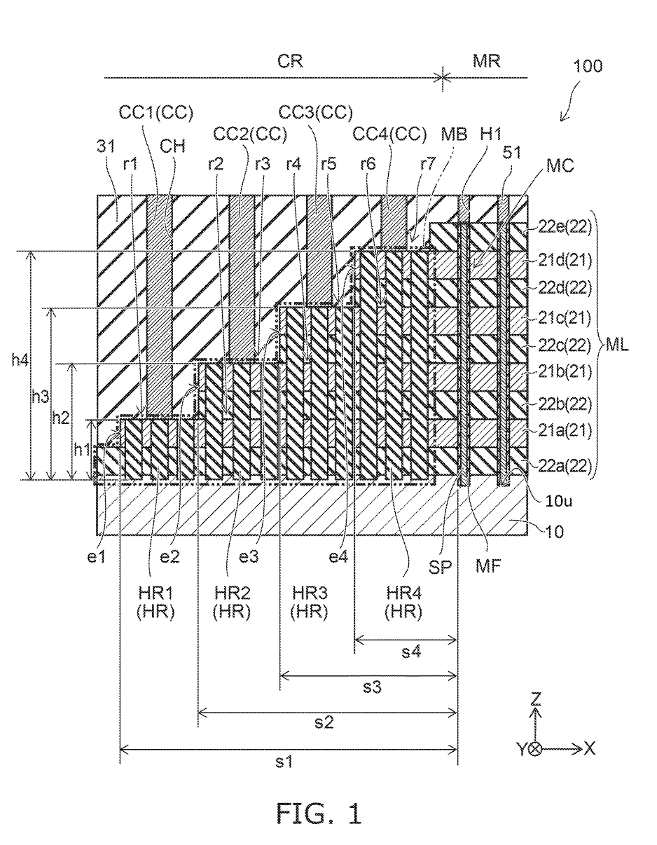

FIG. 1 is a cross-sectional view illustrating a semiconductor memory device according to an embodiment.

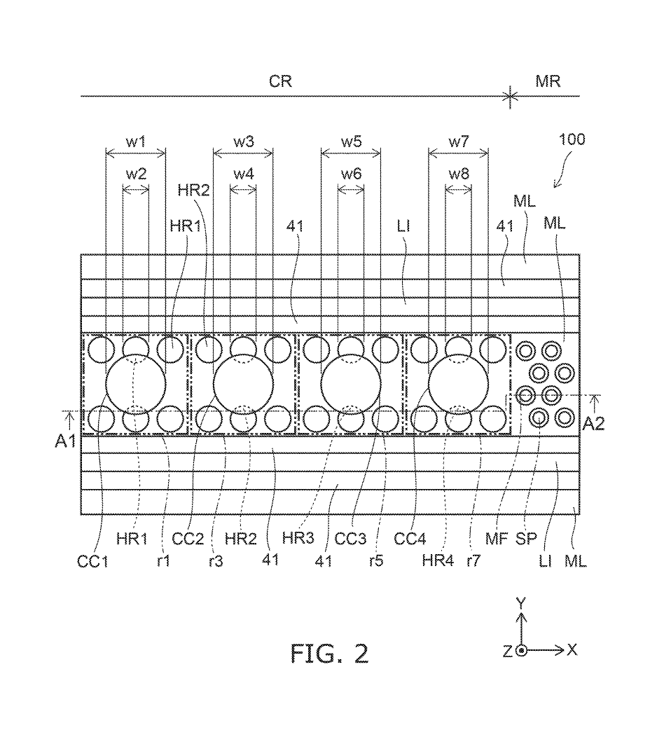

FIG. 2 is a plan view illustrating the semiconductor memory device according to the embodiment.

As shown in FIG. 1, a substrate 10 is provided in the semiconductor memory device 100 according to the embodiment. Semiconductor pillars SP, a stacked body ML, and memory films MF are provided on the substrate 10.

The stacked body ML includes multiple conductive layers 21 and multiple insulating layers 22 stacked alternately. The stacking direction (a first direction) of the multiple conductive layers 21 and the multiple insulating layers 22 is taken as a Z-direction. One direction perpendicular to the Z-direction is taken as an X-direction. A direction perpendicular to the Z-direction and the X-direction is taken as a Y-direction.

The stacked body ML is provided on a surface 10u (the upper surface) of the substrate 10. For example, the surface 10u spreads along the X-Y plane. The Z-direction is substantially perpendicular to the surface 10u.

The multiple conductive layers 21 include, for example, a first conductive layer 21a, a second conductive layer 21b, a third conductive layer 21c, and a fourth conductive layer 21d. The first to fourth conductive layers 21a to 21d are arranged along the Z-direction in this order. The first to fourth conductive layers 21a to 21d are separated from each other in the Z-direction.

For example, the multiple insulating layers 22 include a first insulating layer 22a, a second insulating layer 22b, a third insulating layer 22c, a fourth insulating layer 22d, and a fifth insulating layer 22e. These insulating layers are arranged along the Z-direction in this order. The first to fifth insulating layers 22a to 22e are separated from each other in the Z-direction.

A memory region MR and a connection region CR are set in the semiconductor memory device 100. The multiple conductive layers 21 are provided in the memory region MR and the connection region CR.

The semiconductor pillars SP are provided in the memory region MR. The semiconductor pillars SP extend along the Z-direction through the stacked body ML. The semiconductor pillars SP are electrically connected to the substrate 10.

The memory film MF is provided between the stacked body ML and the semiconductor pillar SP. For example, the memory film MF includes a charge storage film. The regions between the semiconductor pillar SP and the multiple conductive layers 21 are used as memory cells MC.

Multiple connection portions CC are provided in the connection region CR. The multiple connection portions CC extend along the Z-direction. For example, one of the multiple connection portions CC is electrically connected to one of the multiple conductive layers 21.

The stacked body ML includes a staircase portion MB in the connection region CR. In the staircase portion MB, the positions of the end portions of the multiple conductive layers 21 change in a staircase configuration. In other words, the distances between the semiconductor pillar SP and the end portions of the multiple conductive layers 21 shorten as the distance from the substrate 10 lengthens.

In the staircase portion MB, the distances between the semiconductor pillar SP and the end portions of the multiple insulating layers 22 shorten as the distance from the substrate 10 lengthens. By disposing the end portions of the multiple conductive layers 21 in the staircase configuration, the connection between a prescribed connection portion CC and a prescribed conductive layer 21 is easy.

An insulating layer 31 is provided on the stacked body ML. Namely, the insulating layer 31 is provided on the staircase portion MB in the connection region CR and on the stacked body ML in the memory region MR.

In the connection region CR, the multiple connection portions CC extend in the Z-direction through the insulating layer 31. Plugs 51 that extend in the Z-direction through the insulating layer 31 are provided on the semiconductor pillars SP. The plugs 51 are electrically connected to the semiconductor pillars SP.

In the connection region CR, multiple structure bodies HR are provided inside the staircase portion MB of the stacked body ML. The multiple structure bodies HR extend in the Z-direction through the stacked body ML.

In the embodiment, the multiple connection portions CC are connected respectively to the multiple conductive layers 21 and are used as, for example, contact plugs of the multiple conductive layers 21. On the other hand, for example, the multiple structure bodies HR support the multiple conductive layers 21. On the other hand, for example, the multiple structure bodies HR increase the mechanical strength of the multiple conductive layers 21. In the embodiment, at least a portion of the structure bodies HR is provided in a region overlapping the connection portion CC in the Z-direction.

For example, a structure body (e.g., a second structure body HR2) extends in the Z-direction through the multiple conductive layers 21 (a third region r3 and a second region r2 described below). A connection portion (a second connection portion CC2) is electrically connected to the second conductive layer 21b and overlaps at least a portion of the structure body (HR2) in the Z-direction.

Thereby, the connection region CR can be narrow compared to the case where the connection portions CC and the structure bodies HR do not overlap. Thereby, it is possible to increase the density of the semiconductor memory device.

For example, the multiple connection portions CC include a first connection portion CC1, the second connection portion CC2, a third connection portion CC3, and a fourth connection portion CC4.

The end portion of the first conductive layer 21a has a first end surface e1. The end portion of the second conductive layer 21b has a second end surface e2. The end portion of the third conductive layer 21c has a third end surface e3. The end portion of the fourth conductive layer 21d has a fourth end surface e4.

For example, the first end surface e1 and the semiconductor pillar SP are separated in the X-direction. For example, the second end surface e2 and the semiconductor pillar SP are separated in the X-direction. For example, the third end surface e3 and the semiconductor pillar SP are separated in the X-direction. For example, the fourth end surface e4 and the semiconductor pillar SP are separated in the X-direction.

A first distance s1 between the first end surface e1 and the semiconductor pillar SP is longer than a second distance s2 between the second end surface e2 and the semiconductor pillar SP. The second distance s2 is longer than a third distance s3 between the third end surface e3 and the semiconductor pillar SP. The third distance s3 is longer than a fourth distance s4 between the fourth end surface e4 and the semiconductor pillar SP.

The first conductive layer 21a includes a first region r1 not overlapping the second conductive layer 21b in the Z-direction in the connection region CR. The first conductive layer 21a includes the second region r2 overlapping the second conductive layer 21b in the Z-direction in the connection region CR.

The second conductive layer 21b includes the third region r3 not overlapping the third conductive layer 21c in the Z-direction in the connection region CR. The second conductive layer 21b includes a fourth region r4 overlapping the third conductive layer 21c in the Z-direction in the connection region CR.

The third conductive layer 21c includes a fifth region r5 not overlapping the fourth conductive layer 21d in the Z-direction in the connection region CR. The third conductive layer 21c includes a sixth region r6 overlapping the fourth conductive layer 21d in the Z-direction in the connection region CR.

The fourth conductive layer 21d includes a seventh region r7 in the connection region CR.

In the embodiment as shown in FIG. 1, the first region r1 is positioned between the first end surface e1 and the second region r2 in the X-direction. The third region r3 is positioned between the second end surface e2 and the fourth region r4 in the X-direction. The fifth region r5 is positioned between the third end surface e3 and the sixth region r6 in the X-direction. The seventh region r7 is positioned between the fourth end surface e4 and the semiconductor pillar SP in the X-direction.

For example, the first connection portion CC1 is electrically connected to the first region r1 of the first conductive layer 21a. For example, the second connection portion CC2 is electrically connected to the third region r3 of the second conductive layer 21b. For example, the third connection portion CC3 is electrically connected to the fifth region r5 of the third conductive layer 21c. For example, the fourth connection portion CC4 is electrically connected to the seventh region r7 of the fourth conductive layer 21d.

The multiple structure bodies HR include multiple first structure bodies HR1, the multiple second structure bodies HR2, multiple third structure bodies HR3, and multiple fourth structure bodies HR4.

The multiple first structure bodies HR1 overlap a portion of the first region r1 in the Z-direction. The multiple second structure bodies HR2 overlap a portion of the second region r2 and a portion of the third region r3 in the Z-direction. The multiple third structure bodies HR3 overlap a portion of the second region r2, a portion of the fourth region r4, and a portion of the fifth region r5 in the Z-direction. The multiple fourth structure bodies overlap a portion of the second region r2, a portion of the fourth region r4, a portion of the sixth region r6, and a portion of the seventh region in the Z-direction.

The multiple first structure bodies HR1 extend in the Z-direction through the staircase portion MB overlapping the first region r1 in the Z-direction. For example, the multiple first structure bodies HR1 extend in the Z-direction to the position of the surface of the upper surface of the first region r1.

The multiple second structure bodies HR2 extend in the Z-direction through the staircase portion MB overlapping the third region r3 in the Z-direction. In other words, the multiple second structure bodies HR2 extend in the Z-direction through the second region r2 of the first conductive layer 21a and through the third region r3 of the second conductive layer 21b. For example, the multiple second structure bodies HR2 extend in the Z-direction to the position of the surface of the upper surface of the third region r3.

The multiple third structure bodies HR3 extend in the Z-direction through the staircase portion MB overlapping the fifth region r5 in the Z-direction. In other words, the multiple third structure bodies HR3 extend in the Z-direction through the second region r2 of the first conductive layer 21a, through the fourth region r4 of the second conductive layer 21b, and through the fifth region r5 of the third conductive layer 21c. For example, the multiple third structure bodies HR3 extend in the Z-direction to the position of the surface of the upper surface of the fifth region r5.

The multiple fourth structure bodies HR4 extend in the Z-direction through the portion of the staircase portion MB overlapping the seventh region r7 in the Z-direction. In other words, the multiple fourth structure bodies HR4 extend in the Z-direction through the second region r2 of the first conductive layer 21a, through the fourth region r4 of the second conductive layer 21b, through the sixth region r6 of the third conductive layer 21c, and through the seventh region r7 of the fourth conductive layer 21d. For example, the multiple fourth structure bodies HR4 extend in the Z-direction to the position of the surface of the upper surface of the seventh region r7.

A length h1 in the Z-direction of the first structure body HR1 is shorter than a length h2 in the Z-direction of the second structure body HR2. The length h2 in the Z-direction of the second structure body HR2 is shorter than a length h3 in the Z-direction of the third structure body HR3. The length h3 in the Z-direction of the third structure body HR3 is shorter than a length h4 in the Z-direction of the fourth structure body HR4.

The first connection portion CC1 and the multiple first structure bodies HR1 do not overlap in a direction (e.g., the X-direction and the Y-direction) perpendicular to the Z-direction. The second connection portion CC2 and the multiple second structure bodies HR2 do not overlap in a direction (e.g., the X-direction and the Y-direction) perpendicular to the Z-direction. The third connection portion CC3 and the multiple third structure bodies HR3 do not overlap in a direction (e.g., the X-direction and the Y-direction) perpendicular to the Z-direction. The fourth connection portion CC4 and the multiple fourth structure bodies HR4 do not overlap in a direction (e.g., the X-direction and the Y-direction) perpendicular to the Z-direction.

As shown in FIG. 2, the first connection portion CC1 and at least a portion of the multiple first structure bodies HR1 overlap in the Z-direction. The second connection portion CC2 and at least a portion of the multiple second structure bodies HR2 overlap in the Z-direction. The third connection portion CC3 and at least a portion of the multiple third structure bodies HR3 overlap in the Z-direction. The fourth connection portion CC4 and at least a portion of the multiple fourth structure bodies HR4 overlap in the Z-direction.

For example, a portion of the first connection portion CC1 contacts at least a portion of the multiple first structure bodies HR1. For example, another portion of the first connection portion CC1 contacts a portion of the first region r1 of the first conductive layer 21a. For example, the contact surface area between the first structure bodies HR1 and the first connection portion CC1 is less than the contact surface area between the first connection portion CC1 and the first conductive layer 21a. For example, a first contact surface area between the first connection portion CC1 and the first structure bodies HR1 is less than a second contact surface area between the first connection portion CC1 and the first conductive layer 21a. For example, the second contact surface area is greater than 0 percent but not more than 50 percent of the first contact surface area.

For example, a portion of the second connection portion CC2 contacts at least a portion of the second structure bodies HR2. For example, another portion of the second connection portion CC2 contacts a portion of the third region r3 of the second conductive layer 21b. For example, the contact surface area between the second connection portion CC2 and the second structure bodies HR2 is less than the contact surface area between the second connection portion CC2 and the second conductive layer 21b. For example, a third contact surface area between the second connection portion CC2 and the second structure bodies HR2 is less than a fourth contact surface area between the second connection portion CC2 and the second conductive layer 21b. For example, the fourth contact surface area is greater than 0 percent but not more than 50 percent of the third contact surface area.

For example, a portion of the third connection portion CC3 contacts at least a portion of the third structure bodies HR3. For example, another portion of the third connection portion CC3 contacts a portion of the fifth region r5 of the third conductive layer 21c. For example, the contact surface area between the third connection portion CC3 and the multiple third structure bodies HR3 is less than the contact surface area between the third connection portion CC3 and the third conductive layer 21c. For example, a fifth contact surface area between the third connection portion CC3 and the third structure bodies HR3 is less than a sixth contact surface area between the third connection portion CC3 and the third conductive layer 21c. For example, the fifth contact surface area is greater than 0 percent but not more than 50 percent of the sixth contact surface area.

For example, a portion of the fourth connection portion CC4 contacts at least a portion of the fourth structure bodies HR4. For example, another portion of the fourth connection portion CC4 contacts a portion of the seventh region r7 of the fourth conductive layer 21d. For example, the contact surface area between the fourth connection portion CC4 and the multiple fourth structure bodies HR4 is less than the contact surface area between the fourth connection portion CC4 and the fourth conductive layer 21d. For example, a seventh contact surface area between the fourth connection portion CC4 and the fourth structure bodies HR4 is less than an eighth contact surface area between the fourth connection portion CC4 and the fourth conductive layer 21d. For example, the eighth contact surface area is greater than 0 percent but not more than 50 percent of the seventh contact surface area.

A first length w1 in a direction (e.g., the X-direction or the Y-direction) crossing the Z-direction of the first connection portion CC1 is longer than a second length w2 in a direction (e.g., the X-direction or the Y-direction) crossing the Z-direction of one of the multiple first structure bodies HR1.

A third length w3 in a direction (e.g., the X-direction or the Y-direction) crossing the Z-direction of the second connection portion CC2 is longer than a fourth length w4 in a direction (e.g., the X-direction or the Y-direction) crossing the Z-direction of one of the multiple second structure bodies HR2.

A fifth length w5 in a direction (e.g., the X-direction or the Y-direction) crossing the Z-direction of the third connection portion CC3 is longer than a sixth length w6 in a direction (e.g., the X-direction or the Y-direction) crossing the Z-direction of one of the multiple third structure bodies HR3.

A seventh length w7 in a direction (e.g., the X-direction or the Y-direction) crossing the Z-direction of the fourth connection portion CC4 is longer than an eighth length w8 in a direction (e.g., the X-direction or the Y-direction) crossing the Z-direction of one of the multiple fourth structure bodies HR4.

The semiconductor memory device 100 includes an interconnect portion LI. For example, the interconnect portion LI spreads along the Y-Z plane through the stacked body ML and the insulating layer 31. An insulating portion 41 is provided between the interconnect portion LI and the stacked body ML and between the interconnect portion LI and the insulating layer 31. In FIG. 2, the insulating layer 31 and the plugs 51 are not illustrated for easier viewing of the drawing.

In the embodiment, the multiple structure bodies HR are provided in a portion of the staircase portion MB including a region overlapping the connection portion CC in the Z-direction. Because the structure bodies HR are provided also in the region overlapping the connection portion CC in the Z-direction, the structure bodies HR are arranged densely in the staircase portion MB. Thereby, the strength of the staircase portion MB is increased; and the occurrence of shape deformation, film separation, or cracks in the semiconductor memory device partway through the manufacturing, etc., can be suppressed.

By also using the region directly under the connection portion CC as the arrangement locations of the structure bodies HR, it is possible to increase the strength of the semiconductor memory device in a small space. Thereby, the staircase portion MB area can be reduced. Accordingly, higher density of the semiconductor memory device is possible.

A method for manufacturing the semiconductor memory device according to the embodiment will now be described.

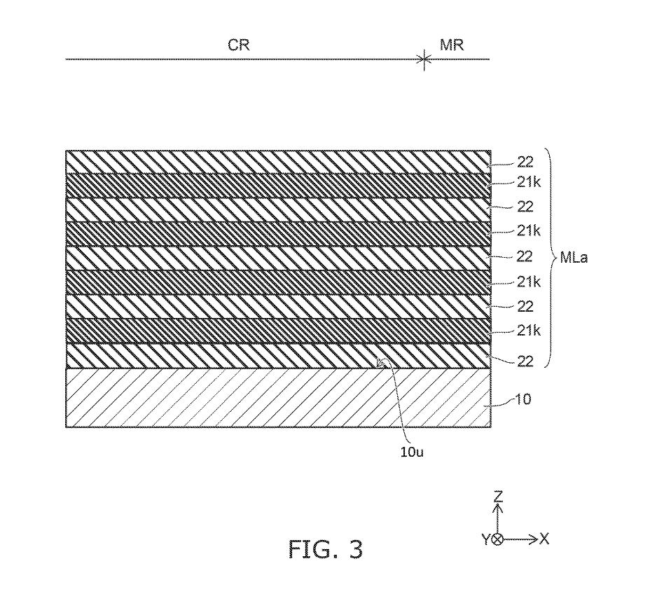

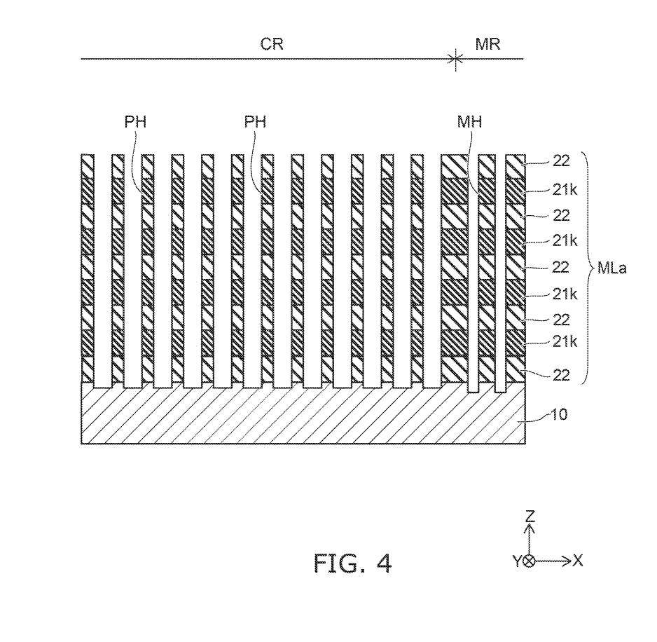

FIG. 3 and FIG. 4 are cross-sectional views of processes, illustrating the method for manufacturing the semiconductor memory device according to the embodiment.

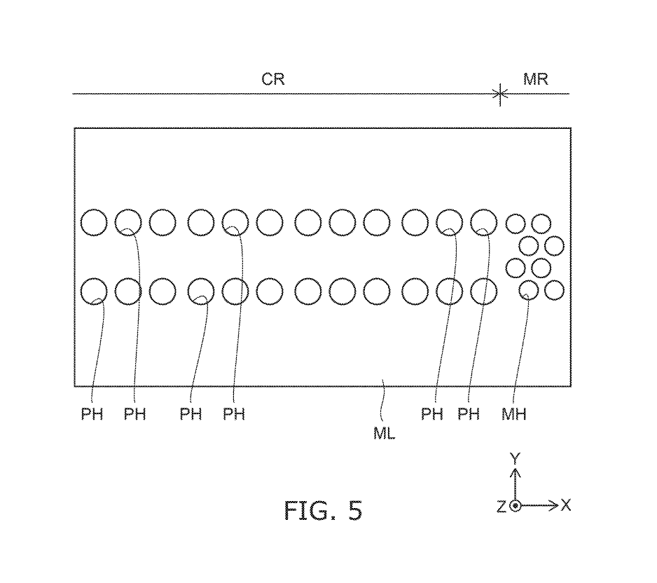

FIG. 5 is a plan view illustrating the method for manufacturing the semiconductor memory device according to the embodiment.

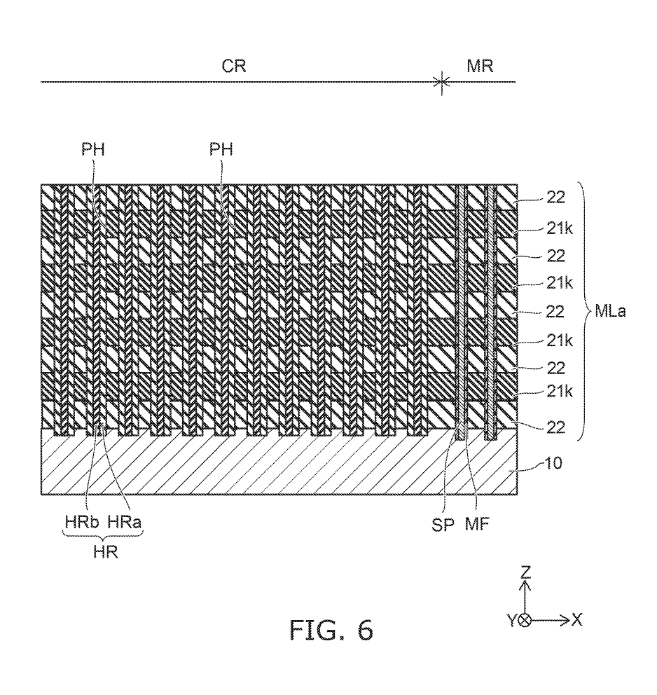

FIG. 6 to FIG. 8 are cross-sectional views of processes, illustrating the method for manufacturing the semiconductor memory device according to the embodiment.

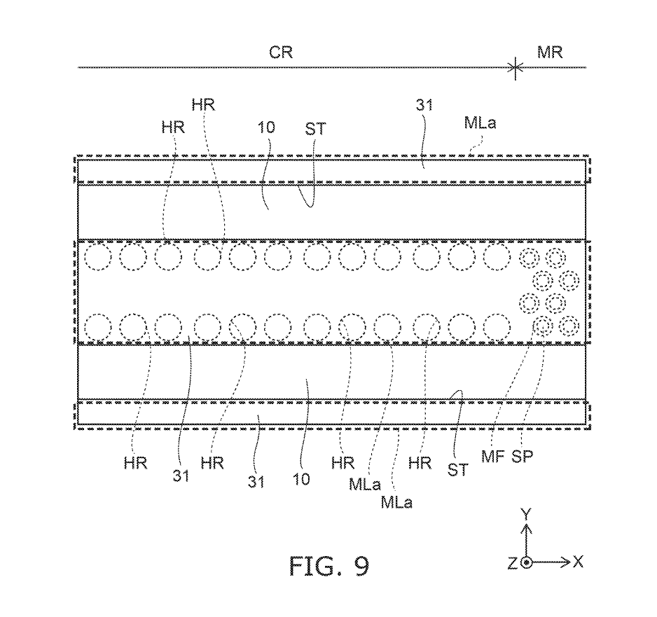

FIG. 9 is a plan view illustrating the method for manufacturing the semiconductor memory device according to the embodiment.

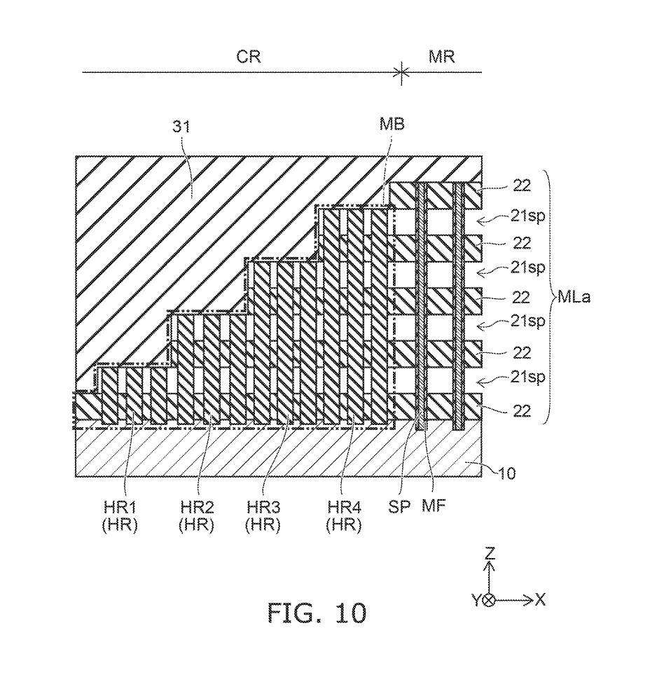

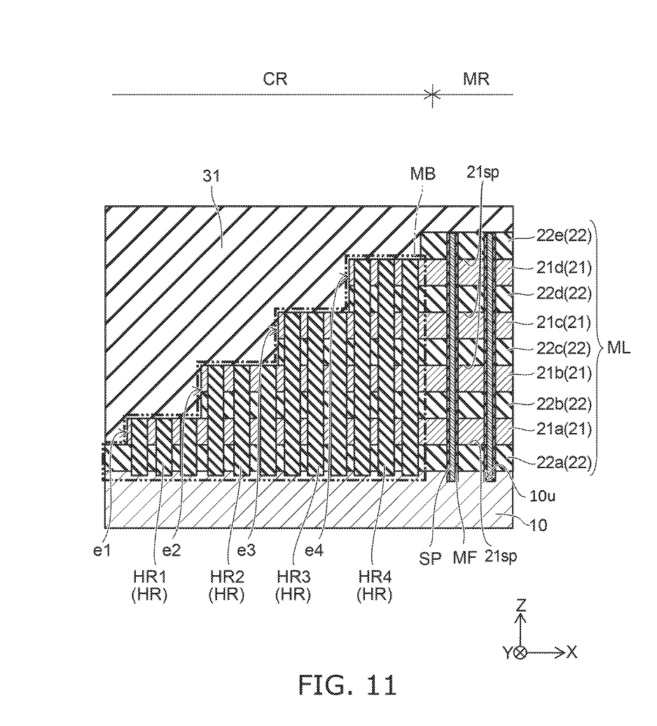

FIG. 10 and FIG. 11 are cross-sectional views of processes, illustrating the method for manufacturing the semiconductor memory device according to the embodiment.

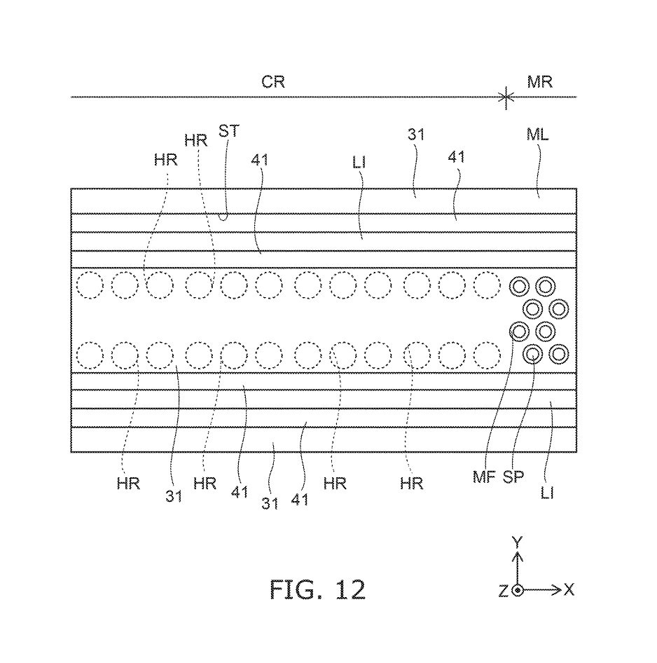

FIG. 12 is a process plan view illustrating the method for manufacturing the semiconductor memory device according to the embodiment.

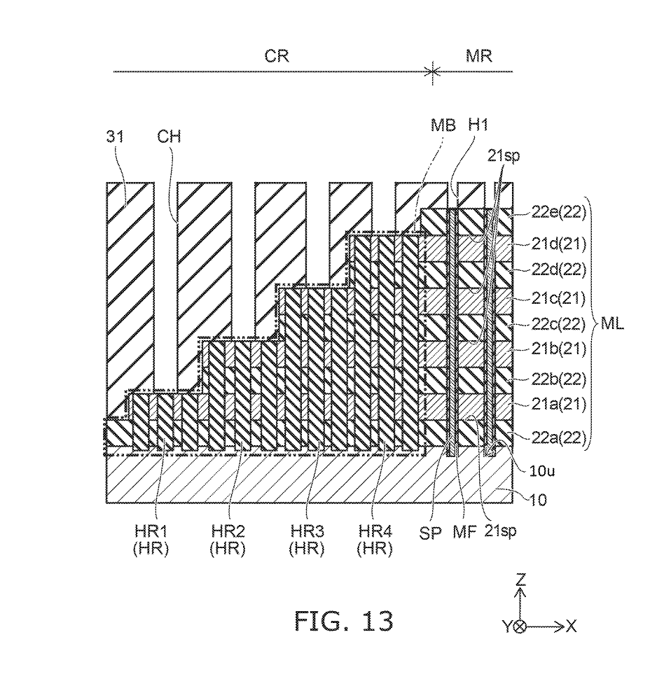

FIG. 13 is a cross-sectional view of a process, illustrating the method for manufacturing the semiconductor memory device according to the embodiment.

The substrate 10 is prepared as shown in FIG. 3. The substrate 10 is, for example, a silicon wafer. The memory region MR and the connection region CR are set in the substrate 10. A stacked body MLa is formed on the substrate 10. The stacked body MLa is formed in the memory region MR and the connection region CR.

The stacked body MLa includes multiple sacrificial layers 21k arranged to be separated from each other in the Z-direction. For example, the stacked body MLa is formed by alternately stacking the insulating layers 22 and the sacrificial layers 21k on the substrate 10. The insulating layers 22 are formed using a material including, for example, silicon oxide. The sacrificial layers 21k are formed using a material including, for example, silicon nitride.

As shown in FIG. 4, a memory hole MH and multiple holes PH are formed in the stacked body MLa by anisotropic etching such as reactive ion etching (RIE), etc. The memory hole MH is formed in the memory region MR. For example, the memory hole MH has a substantially circular columnar configuration. The memory hole MH pierces the stacked body MLa in the Z-direction. A portion of the surface 10u (the upper surface) of the substrate 10 is exposed at the bottom of the memory hole MH.

The multiple holes PH are formed in the connection region CR. For example, the multiple holes PH have substantially circular columnar configurations. The multiple holes PH pierce the stacked body MLa in the Z-direction. For example, a portion of the surface 10u of the substrate 10 is exposed at the bottoms of the multiple holes PH.

As shown in FIG. 5, for example, the multiple holes PH are formed in a matrix configuration in the X-Y plane. An example is described in the embodiment in which the multiple holes PH are formed in a matrix configuration of two rows and twelve columns in the connection region CR.

As shown in FIG. 6, the memory film MF is formed on the side wall of the memory hole MH. The semiconductor pillar SP is formed inside the memory hole MH. The semiconductor pillar SP is electrically connected to the substrate 10.

The structure body HR is formed inside the hole PH. For example, the structure body HR is formed by forming a structure body HRb inside the hole PH after forming a first insulating portion HRa on the side wall of the hole PH.

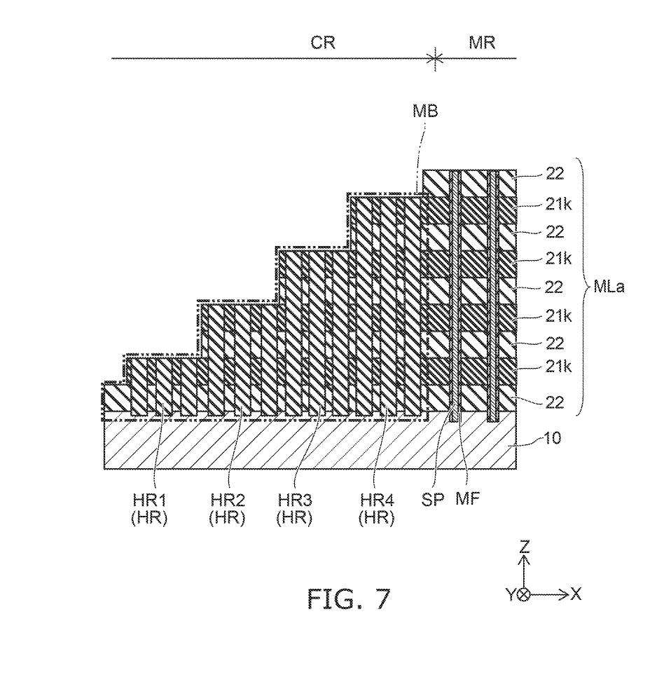

As shown in FIG. 7, the staircase portion MB is formed in the stacked body ML in the connection region CR. The staircase portion MB is formed by forming a mask on the stacked body ML and by alternately repeating the patterning of the stacked body ML using the mask and the slimming of the mask. At this time, the multiple structure bodies HR that are formed inside the stacked body ML also are patterned.

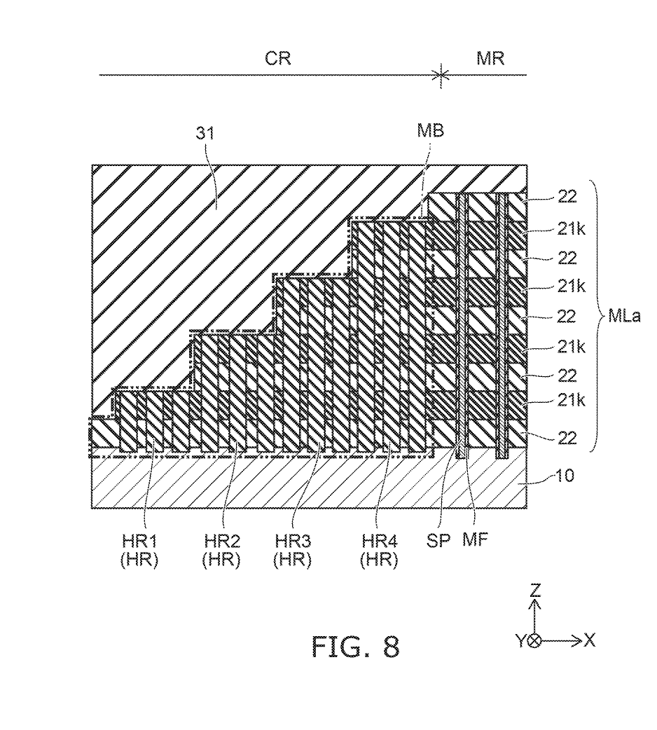

As shown in FIG. 8, the insulating layer 31 is formed on the staircase portion MB of the connection region CR and on the stacked body ML.

As shown in FIG. 9, a slit ST is formed in the stacked body ML and the insulating layer 31. The slit ST spreads along the X-Z plane through the stacked body ML and the insulating layer 31.

For example, an etchant is supplied to the slit ST. Thereby, as shown in FIG. 10, the sacrificial layers 21k that are included in the stacked body MLa are removed by wet etching. In other words, the sacrificial layers 21k are removed by the etchant supplied to the slit ST. The space where the sacrificial layers 21k are removed is used as gaps 21sp. At this time, the structure bodies HR remain inside the stacked body MLa.

For example, the etchant used when etching the sacrificial layers 21k includes, for example, hot phosphoric acid. For example, a drying process may be implemented after the etching. For example, the drying process may be performed use isopropyl alcohol (IPA).

At this time, the multiple structure bodies HR are used as posts. For example, the bending of the insulating layers 22 is suppressed by the multiple structure bodies HR supporting the insulating layers 22 in the region where the sacrificial layers 21k are removed. The yield when etching the sacrificial layers 21k increases.

As shown in FIG. 11, a conductive material such as tungsten or the like is provided inside the gaps 21sp. For example, the conductive material is provided inside the gaps 21sp by chemical vapor deposition (CVD) via the slit ST shown in FIG. 9. Thereby, the conductive layers 21 are formed inside the gaps 21sp. Thereby, the stacked body MLa becomes the stacked body ML.

In the staircase portion MB, the positions of the end portions of the conductive layers 21 change in a staircase configuration. In other words, the distances between the semiconductor pillar SP and the end portions of the multiple conductive layers 21 shorten as the distance from the substrate 10 lengthens.

As shown in FIG. 12, the insulating portion 41 is formed on the side wall of the slit ST. The insulating portion 41 is formed of a material including, for example, silicon oxide. The interconnect portion LI is formed inside the slit ST. The interconnect portion LI is formed of a conductive material such as, for example, tungsten, etc.

As shown in FIG. 13, multiple contact holes CH are formed in the connection region CR. The contact holes CH pierce the insulating layer 31 in the Z-direction. A portion of the contact holes CH overlaps at least a portion of the structure bodies HR in the Z-direction. In the memory region MR, holes H1 are formed on the semiconductor pillars SP. The holes H1 pierce the insulating layer 31 in the Z-direction.

As shown in FIG. 1, a conductive material such as, for example, tungsten or the like is provided inside the contact holes CH. Thereby, the connection portions CC are formed inside the contact holes CH. For example, one of the multiple connection portions CC is electrically connected to one of the multiple conductive layers 21. The plugs 51 are formed inside the holes H1. The plugs 51 are electrically connected to the semiconductor pillars SP. The plugs 51 are formed of a conductive material such as, for example, tungsten, etc.

By implementing the processes recited above, the semiconductor memory device according to the embodiment can be manufactured.

Specific examples of the configuration of the structure body HR will now be described.

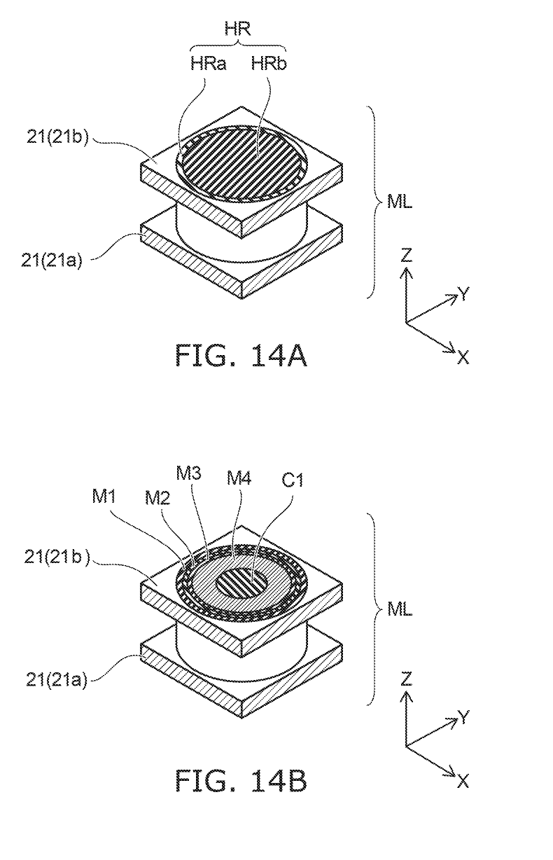

FIG. 14A and FIG. 14B are perspective views illustrating a portion of the semiconductor memory device.

FIG. 14A is a perspective view illustrating an example of the configuration of the structure body HR. FIG. 14B is a perspective view illustrating another example of the configuration of the structure body HR.

As shown in FIG. 14A, the structure body HR includes the first insulating portion HRa and the second insulating portion HRb. For example, the first insulating portion HRa has a tubular configuration. The second insulating portion HRb extends in the Z-direction through the stacked body ML. The first insulating portion HRa is provided between the second insulating portion HRb and the stacked body ML.

The first insulating portion HRa includes, for example, silicon oxide. The second insulating portion HRb includes, for example, silicon nitride.

In another example of the structure body HR shown in FIG. 14B, the structure body HR includes a first film M1, a second film M2, a third film M3, a fourth film M4, and a core insulating portion C1.

As shown in FIG. 14B, the core insulating portion C1 extends in the Z-direction through the stacked body ML. The first film M1 is provided between the core insulating portion C1 and the stacked body ML. The second film M2 is provided between the core insulating portion C1 and the first film M1. The third film M3 is provided between the core insulating portion C1 and the second film M2. The fourth film M4 is provided between the core insulating portion C1 and the third film M3.

The first film M1 includes, for example, at least one of silicon oxide or aluminum oxide. The second film M2 includes, for example, silicon nitride. The third film M3 includes, for example, at least one of silicon oxide or aluminum oxide. The fourth film M4 includes, for example, a semiconductor material such as silicon, etc. The core insulating portion C1 includes, for example, an insulating material such as silicon oxide, etc.

In the embodiment, the multiple structure bodies HR are provided inside the stacked body ML in the connection region CR. The multiple structure bodies HR are provided also directly under the connection portions CC. For example, the multiple structure bodies HR are used as posts. Thereby, the strength of the connection region CR increases. Accordingly, the occurrence of shape deformation, film separation, or cracks of the stacked body ML (MLa) and the substrate 10, etc., can be suppressed. Thereby, the yield of the patterning of subsequent processes increases.

Other examples of the arrangement of the structure bodies HR and the connection portion CC will now be described.

The arrangement in the first region r1 will be described as an example.

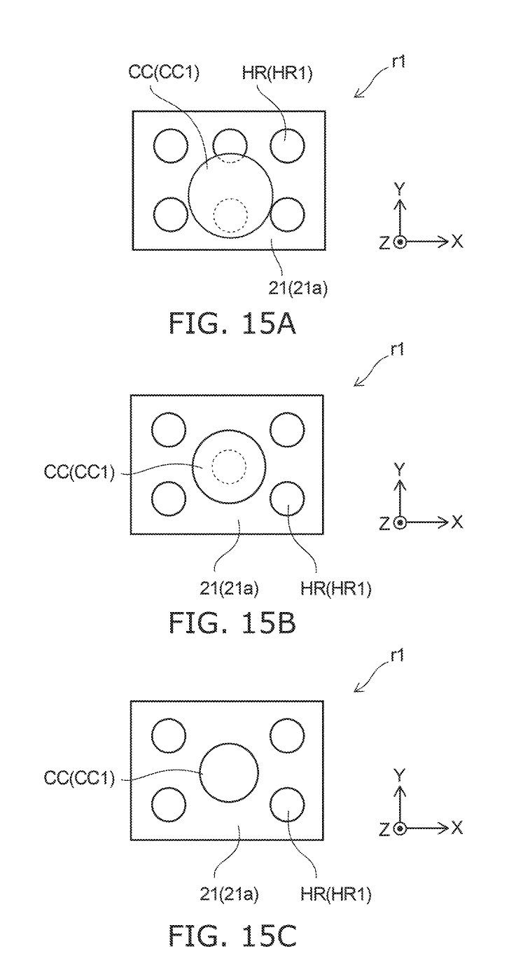

FIG. 15A to FIG. 15C illustrate a portion of the semiconductor memory device.

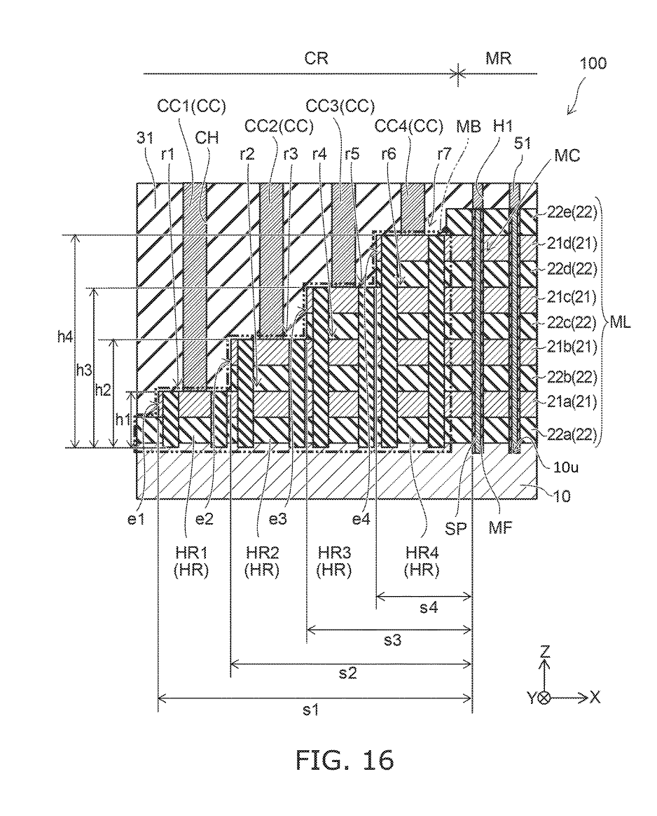

FIG. 16 is a cross-sectional view illustrating the semiconductor memory device according to the embodiment.

FIG. 15A is a plan view showing a first example of the arrangement of the structure bodies HR and the connection portion CC. FIG. 15B is a plan view showing a second example of the arrangement of the structure bodies HR and the connection portion CC. FIG. 15C is a plan view illustrating a third example of the arrangement of the structure bodies HR and the connection portion CC. FIG. 16 is a schematic cross-sectional view corresponding to a cross section along line A1-A2 shown in FIG. 2 of the semiconductor memory device of the third example shown in FIG. 15C.

In FIG. 15A to FIG. 15C, the components other than the structure bodies HR (the first structure bodies HR1), the connection portion CC (the connection portion CC1), and the conductive layer 21 (the first conductive layer 21a) are not illustrated for easier viewing of the drawing.

As shown in FIG. 15A, in the Z-direction, the connection portion CC1 overlaps one of the multiple first structure bodies HR1 and may further overlap a portion of one other of the multiple first structure bodies HR1. For example, the distance between the multiple first structure bodies HR1 in the X-Y plane is 500 nm or less.

As shown in FIG. 15B, in the X-Y plane, the multiple first structure bodies HR1 may be arranged in a hexagonal configuration. In such a case, for example, the first connection portion CC1 overlaps one of the multiple first structure bodies HR1 in the Z-direction. For example, the distance between the multiple first structure bodies HR1 in the X-Y plane is 500 nm or less.

As shown in FIG. 15C, the first connection portion CC1 may not overlap the multiple first structure bodies HR1 in the Z-direction.

As shown in FIG. 16, the second connection portion CC2 may not overlap the multiple second structure bodies HR2 in the Z-direction. The third connection portion CC3 may not overlap the multiple third structure bodies HR3 in the Z-direction. The fourth connection portion CC4 may not overlap the multiple fourth structure bodies HR4 in the Z-direction.

At least a portion of the first connection portion CC1 does not overlap the multiple first structure bodies HR1 in a direction crossing the Z-direction. At least a portion of the second connection portion CC2 does not overlap the multiple second structure bodies HR2 in a direction crossing the Z-direction. At least a portion of the third connection portion CC3 does not overlap the multiple third structure bodies HR3 in a direction crossing the Z-direction. At least a portion of the fourth connection portions CC4 and the fourth structure bodies HR4 do not overlap in a direction crossing the Z-direction.

In the third example of the semiconductor memory device 100, a dense arrangement is possible for the distances in the X-Y direction between the connection portion CC (e.g., the second connection portion CC2) and the structure bodies HR (e.g., the second structure bodies HR2) regardless of the minimum patterning dimension. Accordingly, the connection region CR area can be reduced. Thereby, the semiconductor memory device can be downscaled.

An example of the memory film MF and the semiconductor pillar will now be described.

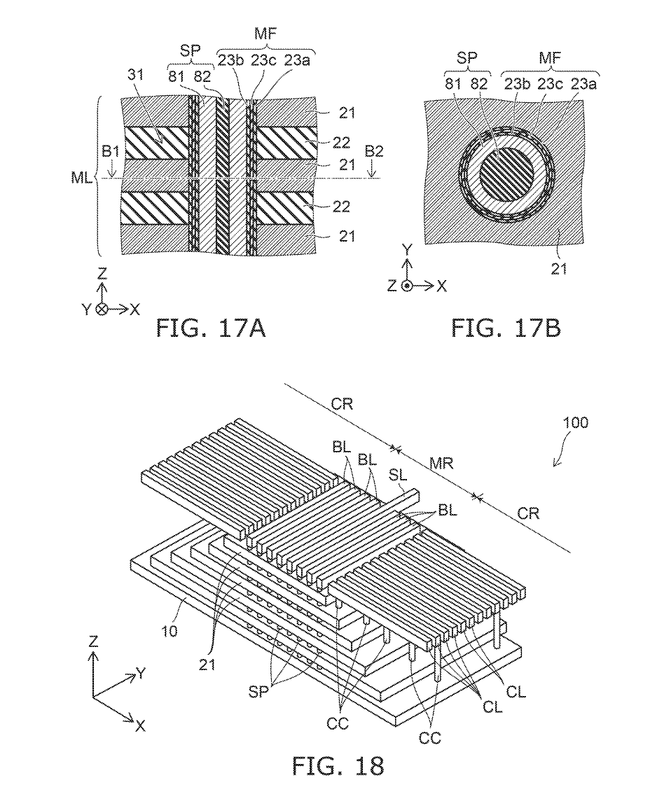

FIG. 17A and FIG. 17B are schematic cross-sectional views illustrating a portion of the semiconductor memory device.

FIG. 17B is a cross-sectional view illustrating a cross section along line B1-B2 shown in FIG. 17A.

As shown in FIG. 17A, the semiconductor pillar SP includes a core insulating portion 82 and a semiconductor film 81. The core insulating portion 82 extends in the Z-direction through the stacked body ML. The semiconductor film 81 is provided between the stacked body ML and the core insulating portion 82.

The memory film MF is provided between the semiconductor pillar SP and the stacked body ML. The memory film MF includes, for example, an outer film 23a, an inner film 23b, and a middle film 23c.

The outer film 23a is provided between the semiconductor pillar SP and the stacked body ML. The inner film 23b is provided between the semiconductor pillar SP and the outer film 23a. The middle film 23c is provided between the outer film 23a and the inner film 23b.

The outer film 23a is, for example, a blocking insulating film. The inner film 23b is, for example, a tunneling insulating film. The middle film 23c is, for example, a charge storage film.

The outer film 23a and the inner film 23b include, for example, at least one of silicon oxide and aluminum oxide. The middle film 23c includes, for example, silicon nitride.

For example, the memory film MF is formed by stacking the outer film 23a, the middle film 23c, and the inner film 23b in this order inside the memory hole MH.

The memory film MF and the semiconductor pillar SP may be formed simultaneously with the pillar HR. In such a case, the configuration of the pillar HR has the configuration shown in FIG. 14B described above.

An example of the semiconductor memory device according to the embodiment will now be described.

FIG. 18 is a perspective view illustrating the semiconductor memory device according to the embodiment.

In FIG. 18, the interconnect portion LI, the multiple pillars HR, and the insulative components are not illustrated to simplify the illustration.

In the semiconductor memory device 100 as shown in FIG. 18, the stacked body ML that includes the multiple conductive layers 21 is provided on the substrate 10. In the X-direction, the end portions of the multiple conductive layers 21 become shorter away from the substrate 10. Thereby, the two ends in the X-direction of the multiple conductive layers 21 have staircase configurations. The staircase configuration portions are the connection regions CR described above.

The memory region MR is between two connection regions CR. The multiple semiconductor pillars SP are provided in the memory region MR. The multiple semiconductor pillars SP extend in the Z-direction through the stacked body ML. In the memory region MR, bit lines BL and a source line SL that extend in the Y-direction are provided on the stacked body ML. Although not illustrated, the bit lines BL and the semiconductor pillars SP are electrically connected by plugs (51). Although not illustrated, the source line SL is electrically connected to the interconnect portion LI via, for example, a plug.

In the connection region CR, interconnects CL that extend in, for example, the X-direction are provided on the stacked body ML. The interconnect CL is electrically connected to one of the multiple conductive layers 21 via the connection portion CC.

According to the embodiments, a semiconductor memory device in which higher density is possible and a method for manufacturing the semiconductor memory device can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device, comprising:
a stacked body including
a first conductive layer, and
a second conductive layer separated, with a first insulating region interposed, from the first conductive layer in a first direction;
a semiconductor pillar extending in the first direction through the stacked body;
a memory film provided between the stacked body and the semiconductor pillar;
a first structure body; and
a first connection portion,
the first conductive layer including a first region and a second region, the first region not overlapping the second conductive layer in the first direction, the second region overlapping the second conductive layer in the first direction;
the first structure body extending in the first direction through the first region to a position of a front surface of the first region,
the first connection portion being electrically connected to the first conductive layer.

2. The device according to claim 1, wherein at least a portion of the first connection portion overlaps the first structure body in the first direction.

3. The device according to claim 1, wherein
the stacked body further includes a third conductive layer separated, with a second insulating region interposed, from the first conductive layer and the second conductive layer in the first direction,
the first conductive layer has a first end surface crossing a second direction and being separated from the memory film in the second direction, the second direction crossing the first direction,
the second conductive layer has a second end surface crossing the second direction and being separated from the memory film in the second direction,
the third conductive layer has a third end surface crossing the second direction and being separated from the memory film in the second direction,
a first distance between the first end surface and the memory film is longer than a second distance between the second end surface and the memory film, and
the second distance is longer than a third distance between the third conductive layer and the memory film.

4. The device according to claim 3, wherein
the second conductive layer includes a third region and a fourth region, the third region not overlapping the third conductive layer in the first direction, the fourth region overlapping the third conductive layer in the first direction,
the first region is positioned between the first end surface and the second region, and
the third region is positioned between the second end surface and the fourth region.

5. The device according to claim 1, wherein the first connection portion does not overlap the first structure body in the first direction.

6. The device according to claim 1, further comprising an insulating layer provided on the stacked body,
the first connection portion extending in the first direction through the insulating layer.

7. The device according to claim 1, wherein
the first structure body includes a first insulating portion and a second insulating portion, the first insulating portion including silicon oxide, the second insulating portion including silicon nitride, and
the first insulating portion is provided between the second insulating portion and the first region.

8. The device according to claim 1, wherein
the first structure body includes a first film, a second film, a third film, a fourth film, and a core insulating portion,
the first film is provided between the core insulating portion and the first region,
the second film is provided between the core insulating portion and the first film,
the third film is provided between the core insulating portion and the second film, and
the fourth film is provided between the core insulating portion and the third film.

9. The device according to claim 1, wherein a length in a second direction of the first connection portion is longer than a length in the second direction of the first structure body, the second direction crossing the first direction.

10. The device according to claim 4, further comprising:
a second structure body extending along the first direction through the second region and through the third region to a position of a front surface of the third region; and
a second connection portion electrically connected to the second conductive layer.

11. The device according to claim 10, wherein a length in the first direction of the second structure body is longer than a length in the first direction of the first structure body.

12. A semiconductor memory device, comprising:
a stacked body including a plurality of conductive layers, the plurality of conductive layers being provided to be separated from each other in a first direction, the stacked body including a staircase portion, positions of end portions of the plurality of conductive layers having a staircase configuration in the staircase portion;
a semiconductor pillar extending in the first direction through the stacked body;
a memory film provided between the stacked body and the semiconductor pillar;
a plurality of structure bodies extending along the first direction through the staircase portion to a position of a front surface of the staircase portion; and
a plurality of connection portions provided on the staircase portion and connected respectively to the plurality of conductive layers.

13. The device according to claim 12, wherein at least one of the plurality of connection portions overlaps a portion of at least one of the plurality of structure bodies in the first direction.

14. The device according to claim 12, wherein a portion of at least one of the plurality of connection portions contacts at least one of the plurality of structure bodies.

15. The device according to claim 12, wherein at least one of the plurality of connection portions does not overlap at least one of the plurality of structure bodies in a second direction crossing the first direction.

16. A method for manufacturing a semiconductor memory device, comprising:
forming a stacked body on a substrate, a memory region and a connection region being set in the substrate, the stacked body including a plurality of first layers arranged to be separated from each other in a first direction;
forming a memory hole piercing the stacked body in the first direction in the memory region, and forming a hole piercing the stacked body in the first direction in the connection region;
a first process of forming a memory film on a side wall inside the memory hole, forming a semiconductor pillar inside the memory hole, and forming a structure body inside the hole;
forming a staircase portion in the connection region by removing a portion of the stacked body and a portion of the structure body;
forming an insulating layer on the stacked body;
forming a slit spreading in the first direction and a second direction through the stacked body and through the insulating layer, the second direction crossing the first direction;
removing the plurality of first layers by using an etchant supplied to the slit;
forming a plurality of conductive layers in a space where the plurality of first layers is removed; and
forming a connection portion piercing the insulating layer in the first direction in the connection region, the insulating layer being electrically connected to one of the plurality of conductive layers.

17. The method according to claim 16, wherein the first process includes the structure body being formed by forming a first insulating portion on a side wall of the hole and by forming a second insulating portion inside the hole.

18. The method according to claim 17, wherein the first layer is formed of a material including silicon nitride, the first insulating portion is formed of a material including silicon oxide, and the second insulating portion is formed of a material including silicon nitride.

19. The method according to claim 16, wherein the first process includes the structure body being formed by forming a first film on a side wall of the hole, forming a second film on an inner wall of the first film, forming a third film on an inner wall of the second film, forming a fourth film on an inner wall of the third film, and forming a core insulating portion inside the hole.

20. The method according to claim 19, wherein the first film is formed using a material including at least one of silicon oxide or aluminum oxide, the second film is formed using a material including silicon nitride, the third film is formed using a material including at least one of silicon oxide or aluminum oxide, the fourth film is formed using a material including silicon, and the core insulating portion is formed using a material including silicon oxide.
